(19) United States
(12) Patent Application Publication
(10) Pub. No.: US 2026/0239541 A1
(43) Pub. Date: Aug. 13, 2026

(54) METHOD FOR PRODUCING A METAL-CERAMIC SUBSTRATE, AND METAL-CERAMIC SUBSTRATE PRODUCED USING SUCH A METHOD

(71) Applicant: Rogers Germany GmbH, Eschenbach (DE)

(72) Inventors: Karsten Schmidt, Eschenbach (DE); Stefan Britting, Schnaittach (DE)

(21) Appl. No.: 19/155,640

(22) PCT Filed: Feb. 13, 2024
(86) PCT No.: PCT/EP2024/053567

§ 371 Date: Aug. 12, 2025

(30) Foreign Application Priority Data
Feb. 14, 2023 (DE) 10 2023 103 509.6

(51) Int. Cl. H05K 3/20; B28D 5/02; H05K 1/03; H05K 3/00

(52) U.S. Cl. CPC H05K 3/20; B28D 5/022; H05K 3/0011; H05K 1/0306; H05K 2203/087; H05K 2203/111; H05K 2203/1131; H05K 2203/1142

(57) ABSTRACT

Method for producing a metal-ceramic substrate (1) intended as a printed circuit board, comprising:
providing a starting block (2) comprising silicon,
detaching (104) a wafer (4) from the starting block (2), in particular from the completely nitrided, partially nitrided or non-nitrided starting block (2),
nitriding (105a) the wafer (4) if the wafer (4) has a first density, and/or the starting block (2) if the starting block (2) has a first density, and
at least one sintering step (105b) for adjusting a second density in the nitrided wafer (4) and/or the nitrided starting block (2), wherein the second density is greater than the first density, and
bonding (107) a metal layer (10) to the nitrided and sintered wafer (30) in order to form a metal-ceramic substrate (1).

### CROSS REFERENCE TO RELATED APPLICATIONS

This application is a National Stage application of PCT/EP2024/053567, filed Feb. 13, 2024, which claims the benefit of German Application No. 10 2023 103 509.6, filed Feb. 14, 2023, both of which are incorporated by reference in their entirety herein.

### BACKGROUND

The present invention relates to a method for producing a metal-ceramic substrate and a metal-ceramic substrate manufactured by such a method.

Metal-ceramic substrates are well known in the prior art as printed circuit boards or circuit boards, for example from DE 10 2013 104 739 A1, DE 19 927 046 B4 and DE 10 2009 033 029 A1. Typically, connecting areas for electrical components and conductor paths are arranged on one component side of the metal-ceramic substrate, wherein the electrical components and the conductor paths can be interconnected to form electrical circuits. Essential components of the metal-ceramic substrates are an insulating layer, which is preferably produced from a ceramic, and at least one metal layer bonded to the insulating layer. Due to their comparatively high insulation strengths, insulating layers produced from ceramic have proven to be particularly advantageous in power electronics. Conductor paths and/or connecting areas for the electrical components can then be created by structuring the metal layer.

Silicon nitride has proven to be particularly advantageous as a ceramic element. Silicon nitride is characterized by a comparatively high insulation strength. It also has high thermal conductivity, which is particularly advantageous when using the metal-ceramic substrate as a printed circuit board, as high-performance electronic components generate comparatively large amounts of heat. This heat must be dissipated to prevent damage to the printed circuit board and/or the electronic component. Silicon nitride ceramics are typically produced by manufacturing a slurry-like flat product from silicon nitride powder or granulate, for example by a film casting process. Subsequent sintering converts the flat product into a solid body that can be used as a ceramic element in a metal-ceramic substrate. A corresponding example of such a production process can be found in US 2016 0 362 592A 1. Another example of the production of a silicon nitride ceramic by a film casting process is known from U.S. Pat. No. 6,242,374 B1.

Furthermore, it is already known from JP 2003 248 137 A to detach individual silicon nitride wafers from a block and then use them as metal-ceramic substrates in a bonding process. It is also known from DE 10 2017 211 320 to manufacture a starting block from Si₃N₄ powder, from which a silicon nitride disc is removed after sintering. However, these methods have proven to be particularly tool-intensive and complex.

Based on the prior art, the present invention aims to simplify the production of metal-ceramic substrates whose ceramic element essentially comprises silicon nitride. In particular, the method is intended to simplify the production of silicon nitride ceramics in which disc-like elements are removed from a block element.

### SUMMARY

The present invention solves this problem with the disclosed method and the disclosed metal-ceramic substrate. Further embodiments and examples are described in the description, the dependent claims, and the figures.

According to a first aspect of the present invention, a method for producing a metal-ceramic substrate intended as a printed circuit board is provided, comprising:
providing a starting block comprising silicon,
detaching a wafer from the starting block, in particular from the completely nitrided, partially nitrided or non-nitrided starting block,
nitriding the wafer if the wafer has a first density, and/or the starting block if the starting block has a first density, and
at least one sintering step for adjusting a second density in the nitrided wafer and/or the nitrided starting block, wherein the second density is greater than the first density, and
bonding a metal layer to the nitrided and sintered wafer in order to form a metal-ceramic substrate.

### BRIEF DESCRIPTION OF DRAWINGS

Further advantages and properties result from the following description of preferred embodiments of the invention with reference to the accompanying figures. The following are shown:

FIG. 1 shows a metal-ceramic substrate according to a first exemplary embodiment;

FIG. 2 shows a schematic representation of part of a method for producing a metal-ceramic substrate according to a first exemplary embodiment;

FIG. 3 shows a schematic representation of part of a method for producing a metal-ceramic substrate according to a second exemplary embodiment; and

FIG. 4 shows a schematic representation of a further part of a method for producing a metal-ceramic substrate according to a second exemplary embodiment.

### DETAILED DESCRIPTION

In contrast to the prior art, it is provided that silicon is used as the starting material, which is pressed into a starting block or a block element. It has been shown that this starting block formed from silicon or a wafer removed from the starting block is also suitable for successful nitriding, provided that during nitriding a first density is present which is lower than the second density produced by the at least one sintering step and is present in the ceramic element of the produced metal-ceramic substrate. In particular, the first density allows nitrogen to penetrate into corresponding pores and causes there the desired nitriding. In particular, it has been shown that an entire starting block can also be nitrided. For this purpose, a first density is set in the starting body which allows nitriding, in particular also of the starting block, preferably of the entire starting block. The starting block has a thickness which is at least ten times greater than the thickness of the detached wafer. Nitriding can take place before and/or after detachment of the wafer. In principle, it is also conceivable that the at least one sintering step takes place before or after the detachment. The at least one sintering step is characterized in that the silicon nitride, whether in the starting block or in the nitrided wafer, obtains its second density, i.e., the final density for the metal-ceramic substrate to be produced, during the at least one sintering step. The provision of the starting block made of silicon thus makes the production of the ceramic element made of silicon nitride, in which a starting block is used, more flexible.

It is preferably provided that the at least one sintering step is performed after the detachment. In contrast to the methods known from the prior art, it is thus provided that the silicon nitride ceramic is not removed from a completely sintered silicon nitride starting block, but that a starting block is provided whose first density is lower than the second density provided in the produced metal-ceramic substrate in the ceramic element. This proves to be particularly advantageous because it means that, prior to detachment, in particular by sawing, the starting block has a porosity which simplifies sawing. In particular, the porosity also proves to be advantageous because a wafer with a first density can be removed from the silicon block, which proves to be advantageous for nitriding, in particular for the conversion efficiency during nitriding.

Preferably, the initial density is between 50% and 95% of the maximum theoretically possible, densest packing. Most preferably, a first density is set between 60% and 90%, most preferably between 60% and 80%, and most preferably between 60% and 70% of the maximum theoretically possible, densest packing in order to set the highest possible porosity.

It is also conceivable that the silicon-comprising starting block also has a proportion of silicon nitride. In this case, a proportion of the starting block or wafer is already nitrided before the actual nitriding is performed. This simplifies the nitriding. For example, the ratio of silicon nitride to silicon is between 0.01 and 0.5, more preferably between 0.01 and 0.3 and most preferably between 0.01 and 0.15, or a ratio of silicon to silicon nitride of between 0.01 and 0.5, preferably between 0.01 and 0.3 and most preferably between 0.01 and 0.15.

Depending on the timing of the nitriding and/or a proportion of silicon nitride in the starting block provided, which is pressed from a corresponding powder or granulate mixture, a nitrided, partially nitrided or non-nitrided starting block is present in particular. In particular, it is apparent to the skilled person that the detachment, nitriding and at least one sintering step can be performed in any technically sensible sequence.

For nitriding, the detached wafer is exposed to a nitrogen-containing atmosphere comprising, for example, ammonia, N2H2 or nitrogen. The nitriding is carried out in particular in a kiln whose temperature is greater than 1000° C., in particular between 1000° C. and 1600° C. and most preferably between 1100° C. and 1500° C. and most preferably between 1100° C. and 1410° C.

The metal-ceramic substrate is preferably formed as a printed circuit board in which, in the produced state, the at least one metal layer bonded to the ceramic element is structured. For example, it is provided that after the bonding step, structuring is also carried out, for example by laser, etching and/or mechanical processing, with which conductor paths and/or connections for electrical or electronic components are realized. It is preferably provided that a further metal layer, in particular a backside metallization and/or a cooling element, is provided on a produced metal-ceramic substrate on the ceramic element on the side opposite the metal layer. The backside metallization preferably serves to counter-act deflection, and the cooling element serves to effectively dissipate heat generated during operation of electrical or electronic components bonded to the printed circuit board or the metal-ceramic substrate.

The materials for the at least one metal layer and/or the at least one further metal layer in the metal-ceramic substrate or ceramic element are copper, aluminum, molybdenum, tungsten, nickel and/or their alloys such as CuZr, AISi or AIMgSi, as well as laminates such as CuW, CuMo, CuAl and/or AICu or MMC (metal matrix composite), such as CuW, CuM or AlSiC, are conceivable. Furthermore, it is more preferably provided that the at least one metal layer on the produced metal-ceramic substrate, in particular as component metallisation, is surface-modified. As a surface modification, for example, sealing with a precious metal, in particular silver; and/or gold, or (electroless) nickel or ENIG (“electroless nickel immersion gold”) or edge encapsulation on the metallisation to sup-press crack formation or propagation is conceivable.

It is preferably provided that the nitriding takes place before the at least one sintering step. This advantageously exploits the fact that the detached wafer or starting block has the first density, which is reduced compared to the second density, thus allowing the nitrogen to penetrate deeper into the wafer and, in particular, increasing the conversion efficiency.

The nitriding can also be performed on the starting block comprising silicon.

Preferably, a pre-sintering step is provided before detachment in order to set the first density. Alternatively, it is conceivable that, without a pre-sintering step, a green compact or the starting block as a green compact is used to detach individual wafers from it. The pre-sintering to set the initial density makes the starting block easier to handle, especially if the starting block is to be placed in a suitable saw or sawing instrument. In the event of cutting or detaching the wafer from a starting block which is essentially provided as a green compact, the pre-sintering step is advantageously omitted.

It is preferably provided that the temperature in the pre-sintering step is greater than 1700° C., more preferably greater than 1800° C. and most preferably between 1900° C. and 2100° C. This allows, for example, temperatures to be used that are higher than the sintering temperatures specified in CN 109 400 176 A and CN 109 400 175 A. It is most preferably provided that the temperature in the pre-sintering step is higher than during sintering after detachment. It has been shown that the very high temperature during pre-sintering results in a mechanically more stable starting block, especially in comparison to blocks that are sintered at lower temperatures. The mechanically more stable starting block is easier to saw than blocks that have been pre-sintered at lower temperatures. In particular, this prevents shear forces from being transferred to the starting block during sawing. In addition, the starting block can be cooled more quickly, as the probability of crack formation or damage to the starting block during cooling is reduced. Furthermore, the time required for sintering after detachment can be reduced. Another advantage is that the starting block is easier to demold after pre-sintering.

It is more preferably provided that the sintering step after detachment is shorter than the pre-sintering step. This advantageously reduces the total time required for the manufacturing process.

Furthermore, it is preferred that the pressure during sintering after detachment is greater than the pressure during pre-sintering. This advantageously makes it possible to form a compact body which can be used as a ceramic element in a metal-ceramic substrate. It also proves advantageous if the pressure before detachment is lower in order to set the porosity in the pre-sintered or partially sintered starting block as high as possible so that the sawing process can be performed with comparatively little effort.

It is more preferably provided that a surface structure, in particular a periodically repeating surface structure, is realized during detachment. Preferably, this is a wave-shaped surface structure which can be realized, for example, by using a sawing wire and/or multiple passes. The surface structure proves to be particularly advantageous because it allows several detached wafers to be stacked on top of each other for sintering after detachment without the need for a separating element to be arranged between the stacked wafers.

Sintering after detachment is therefore more preferably carried out without a separating element such as a powder, a layer or a film. This also eliminates the need for cleaning the wafer after sintering, thus making the entire sintering process less time-consuming as this step can be omitted.

In particular, the surface of the wafer is surface-modulated, preferably with a half-period which is between 5 μm and 1 mm, more preferably between 10 μm and 0.5 mm and most preferably between 200 μm and 100 μm. The surface modulation is preferably part of the microstructuring. For example, this may be a wave-like surface modulation. In contrast to roughness, the surface modulation occurs on a larger scale and is at least one order of magnitude larger than the roughness. Preferably, it is provided that an amplitude of the surface modulation is at least 1 μm, preferably at least 2.5 μm and most preferably between 2 and 4 μm.

If a two-stage sintering step is provided, in which the pre-sintering step takes place before the wafer is detached and the at least one sintering step takes place after the wafer has been detached, a reduced sinter skin forms compared to silicon nitride ceramics produced in the usual manner in a single sintering step. In the ceramic elements formed by film casting followed by sintering, a layer approximately 20 μm to 30 μm thick is ultimately formed, in which sintering agents accumulate, diffusing to there during sintering. This is referred to as the sinter skin. Examples of sintering agents are MgO or Y₂O₃. Similarly, in the case of a reduced sinter skin, a layer thickness in which sintering agents are accumulated is to be expected, which is smaller than 20 μm. The proposed approach, in which pre-sintering and at least one sintering are used, thus results in a reduced thickness of the sinter skin on the ceramic element as a structural feature.

It is preferably provided that a powder and/or a granulate is pressed to provide a silicon-comprising starting block. In particular, it is provided that silicon powder is provided first to provide a silicon-comprising starting block. To support the sintering process, the powder comprises magnesium oxide or yttrium oxide or other sintering aids in addition to silicon. In order to form a starting block, it has proven particularly advantageous to granulate the powder, in particular to convert it into an organically bound granulate, which is produced, for example, by spray granulation or build-up granulation. It is also conceivable that the starting powder comprises at least a proportion of silicon nitride in addition to silicon. For example, the ratio of silicon nitride powder to silicon is between 0.01 and 0.5, more preferably between 0.01 and 0.3 and most preferably between 0.01 and 0.15, or a ratio of silicon to silicon nitride powder of between 0.01 and 0.5, preferably between 0.01 and 0.3 and most preferably between 0.01 and 0.15. Preferably, the proportion of silicon in the powder is greater than 80%, preferably greater than 85% and most preferably greater than 90%. Furthermore, it is conceivable that the powder or granulate comprises a sintering aid in order to improve the sintering processes accordingly. Preferably, the proportion of the sintering agent comprises 1 to 9 weight percent, preferably 2 and 7 weight percent and most preferably 3 and 5 weight percent.

It is also conceivable that the powder and/or granulate comprises a catalyst such as nickel and/or iron, which prove to be advantageous for the subsequent nitriding process. In particular, the proportion of the catalyst is between 100 and 5000 ppm, more preferably between 200 and 2000 ppm and most preferably between 300 and 1000 ppm.

Furthermore, it is preferred that a sawing device, in particular a wire saw and most preferably a multi-wire saw, is used for detaching the wafer. Removal by means of a sawing device and/or a saw proves to be particularly advantageous because it allows the thickness of the ceramic element to be adjusted individually. This makes it easy to change production if a desired silicon nitride ceramic thickness is to be changed. In this case, only the sawing device needs to be adjusted and the cut must be made at a different point in the starting block. This makes it possible, for example, to manufacture comparatively thick silicon nitride ceramics or comparatively thin silicon nitride ceramics that differ from those produced using other standardized methods. Preferably, the sawing device uses a wire, wherein the wire is most preferably a diamond wire and/or a steel wire with a silicon carbide and/or diamond coating. It is also conceivable that a steel wire with a so-called slurry is used as the wire, wherein the slurry comprises a hard material, e.g. SiC or B4C, in a suitable grain size and a cooling lubricant, e.g. PEG (polyethylene glycol).

According to a further embodiment of the present invention, it is provided that the metal layer is bonded to the ceramic element formed from the nitrided wafer by means of an active soldering process and/or hot isostatic pressing.

For example, it is provided that a method for producing a metal-ceramic substrate is provided, comprising:
providing a solder layer, in particular in the form of at least one solder foil or brazing foil,
coating the ceramic element, in particular the nitrided silicon wafer, and/or the at least one metal layer and/or the at least one solder layer with at least one active metal layer,
arranging the at least one solder layer between the ceramic element and the at least one metal layer along a stacking direction to form a solder system comprising the at least one solder layer and the at least one active metal layer, wherein a solder material of the at least one solder layer is preferably free of a material lowering the melting point or of a phosphorus-free material, and
bonding the at least one metal layer to the at least one ceramic layer via the solder system by means of an active soldering process.

In particular, a multi-layer soldering system comprising at least one solder layer, preferably free of elements lowering the melting point, most preferably comprising a phosphorus-free solder layer, and at least one active metal layer is provided. The separation of the at least one active metal layer and the at least one solder layer proves to be particularly advantageous because comparatively thin solder layers can be achieved, especially if the solder layer is a foil. For active metal-containing solder materials, comparatively large solder layer thicknesses would otherwise be necessary due to the brittle intermetallic phases or the high modulus of elasticity and high yield strength of the common active metals and their intermetallic phases, which prevent the deformation of the solder paste or solder layer, thus limiting the minimum layer thickness due to the manufacturing properties of the solder material containing active metal. Accordingly, for solder layers containing active metals, it is not the minimum thickness required for the joining process that determines the minimum solder layer thickness, but rather the technically feasible minimum layer thickness of the solder layer that determines the minimum solder layer thickness. This makes this thicker solder layer containing active metals more expensive than thin layers. The term “phosphorus-free” is understood by those skilled in the art to mean in particular that the phosphorus content in the solder layer is less than 150 ppm, less than 100 ppm and most preferably less than 50 ppm.

In particular, the use of a separately designed active metal layer makes it possible to design this layer comparatively thin, thus enabling the comparatively thin thicknesses of the bonding layer required by the invention to be achieved, in particular averaged over different measured values within the defined area or areas. For example, the active metal layer is thinner than 25 μm, more preferably thinner than 18 μm and most preferably thinner than 12 μm or even thinner than 1000 nm, for example between 400 nm and 800 nm. Examples of active metals are titanium (Ti), zirconium (Zr), hafnium (Hf), chromium (Cr), niobium (Nb), cerium (Ce), tantalum (Ta), magnesium (Mg), lanthanum (La), and vanadium (V). It should be noted that the metals La, Ce, Ca, and Mg are easily oxidizing. It should also be noted that the elements Cr, Mo and W are not classic active metals, but are suitable as a contact layer between Si₃N₄ and the at least one metal layer or the solder system or solder material, since they do not form intermetallic phases with the at least one metal layer, for example copper, and have no marginal solubility.

Preferably, the proportion of active metal in a bonding agent layer comprising active metal or in the active metal layer is greater than 15 weight percent, more preferably greater than 20 weight percent and most preferably greater than 25 weight percent.

Preferably, the solder layer, in particular the phosphorus-free solder layer, comprises several materials in addition to the pure metal. For example, indium is a component of the solder material used in the solder layer. The solder layer or a solder base material preferably has an active metal content of less than 1.5 weight percent, preferably less than 1.0 weight percent and most preferably less than 0.5 weight percent. In particular, the solder base material is free of active metal.

Furthermore, it is conceivable that the solder material for forming the solder layer is de-posited on the active metal layer and/or the at least one metal layer by physical and/or chemical vapor deposition and/or electroplating. This makes it possible, in an advantageous manner, to achieve comparatively thin solder layers in the solder system, in particular in a homogeneous distribution.

For example, in the production of the metal-ceramic substrate, in particular the metal-ceramic substrate, further steps are provided, comprising:
providing a ceramic element and a metal layer,
providing a gas-tight container which encloses the ceramic element, wherein the container is preferably formed from the metal layer or comprises the metal layer,
forming the metal-ceramic substrate by bonding the metal layer to the ceramic element by means of hot isostatic pressing,

wherein, in order to form the metal-ceramic substrate, an active metal layer or a contact layer comprising an active metal is arranged at least in sections between the metal layer and the ceramic element to support the bonding of the metal layer to the ceramic element. The container is preferably formed as a metal container from a metal layer and/or a further metal layer. Alternatively, it is also conceivable that a glass container is used.

In hot isostatic pressing, it is in particular provided that the bonding is carried out by heating under pressure, in which the first and/or second metal layer of the metal container, in particular the subsequent metal layer of the metal-ceramic substrate and any eutectic layer occurring there, does not pass into the melting phase. Accordingly, lower temperatures are required for hot isostatic pressing than for a direct metal bonding method, in particular a DCB method.

Compared to the bonding of a metal layer to a ceramic layer by means of a solder material, in which temperatures below the smelting temperature of the at least one metal layer are usually used, the present method advantageously dispenses with a solder base material and only an active metal is required. The use or application of pressure during hot isostatic pressing also proves to be advantageous because it reduces air inclusions or cavities between the first metal layer and/or the second metal layer on the one hand and the ceramic element on the other hand, thus reducing or even preventing the incidence of blowholes in the formed or produced metal-ceramic substrate. This has a beneficial effect on the quality of the bond between the metal layer or the first and/or second metal layer of the metal container and the ceramic element. In addition, it is advantageously possible to simplify the “second etching” and to avoid solder residues and silver migration.

It is also conceivable that during hot isostatic pressing, an additional solder material is introduced between the ceramic element and the at least one metal layer, wherein a smelting temperature of the additional solder material may be lower than the temperature at which the hot isostatic pressing is performed, i.e. lower than the smelting temperature of the at least one metal layer.

It is preferably provided that, during hot isostatic pressing, the metal container in a heating and a pressure device is subjected to a gaseous pressure of between 100 and 2000 bar, preferably between 150 and 1200 bar and particularly preferably between 300 and 1000 bar, and a processing temperature of 300° C. to a smelting temperature of the at least one metal layer, in particular to a temperature below the smelting temperature., It has been shown to be advantageous that it is thus possible to bond a metal layer, i.e. a first and/or second metal layer of the metal container, to the ceramic element without the temperatures required for a direct metal bonding method, for example a DCB or DAB method, and/or without a solder base material used in active soldering. In addition, the use of a corresponding gaseous pressure makes it possible to produce a metal-ceramic substrate with as few cavities as possible, i.e. without gas inclusions between the metal layer and the ceramic element. In particular, process parameters are used which are mentioned in DE 2013 113 734 A1 and to which explicit reference is made herein.

This achieves an optimum bond between the metal layer and the ceramic element for the intended application, which is particularly easy to structure in order to be able to use the metal-ceramic substrates as printed circuit boards.

It is most preferably provided that the metal layer is structured to form a metallisation, for this purpose, it is particularly preferred that the metal layer is etched or processed with laser light and/or mechanically processed in order to remove metal from the metal layers, in particular down to the ceramic element, in order to produce individual metal sections in the metal layer which are electrically insulated from one another via the ceramic element. This makes it possible to produce conductor paths and/or connecting areas which give the metal-ceramic substrate the character of a printed circuit board.

According to a further embodiment, it is conceivable that the detached wafer has at least partially a wedge-shaped form. This allows, for example, ceramic elements to be provided for printed circuit boards whose front and back sides do not run completely parallel to each other. This also has the advantage, for example, that the insulation strength can be varied homogeneously or continuously via the printed circuit board.

Another subject matter of the present invention is a metal-ceramic substrate manufactured using the method according to the invention. The advantages and properties described in connection with the method apply analogously to the manufactured metal-ceramic substrate and vice versa.

According to a preferred embodiment of the present invention, it is provided that in the produced metal-ceramic substrate a bonding layer is formed between the metal layer and the ceramic element, in particular the silicon nitride layer, wherein a bonding agent layer of the bonding layer has a sheet resistance which is greater than 5 ohms/sq, more preferably greater than 10 ohms/sq and most preferably greater than 20 ohms.

The sheet resistance is directly related to the proportion of active metal in the bonding agent layer, which is decisive for the bonding of the at least one metal layer to the ceramic element. The sheet resistance increases with decreasing active metal content in the bonding layer. A correspondingly high sheet resistance therefore corresponds to a low active metal content in the bonding agent layer.

The sheet resistance does not depend on a single parameter, but can be influenced by the interaction of several parameters. For example, the purity of the active metal, the thickness of the bonding layer and/or the surface roughness of the ceramic element also contribute to determining the sheet resistance. In particular, high sheet resistances can only be achieved through the interaction of at least two parameters.

It has been shown that with increasing active metal content, the formation of brittle inter-metallic phases is favored, which in turn is detrimental to the pull-off strength of the metal layer on the insulating layer. In other words, the sheet resistances required describe bonding layers whose pull-off strength is improved, i.e. increased, due to the reduced formation of brittle intermetallic phases. By specifically adjusting the required sheet resistances, particularly strong bonds between the at least one metal layer and the ceramic element can be achieved. Such increased bonding strength has a beneficial effect on the service life of the metal-ceramic substrate. To determine the sheet resistance, it is provided that the metal layer and, if necessary, a solder base layer are first removed from the produced metal-ceramic substrate, for example by etching. A sheet resistance is then measured on the outer side or bottom side of the metal-ceramic substrate freed from the at least one metal layer and the solder base layer by means of a four-point measurement. In particular, the sheet resistance of a material sample is understood to be its resistance relative to a square surface area. It is customary to designate the surface resistance in ohms/sq (square). The physical unit of sheet resistance is ohms. It is preferably provided that a thickness of the bonding layer measured in the stacking direction, averaged via a plurality of measuring points within a predetermined area or in a plurality of areas running parallel to the main extension plane, has a value which is less than 0.20 mm, more preferably less than 10 μm and most preferably less than 6 μm. Where reference is made to several areas, this means in particular that the at least one metal layer is divided into areas of as equal a size as possible and that at least one value, preferably several measured values, for the thickness are recorded in each of these areas dividing the at least one metal layer. The thicknesses determined in this way at different locations are arithmetically averaged.

Compared to the metal-ceramic substrates known from the prior art, a comparatively thin bonding layer is thus formed between the at least one metal layer and the ceramic element. It is provided that, in order to determine the relevant thickness of the bonding layer, the measured thicknesses are averaged via a plurality of measuring points which are located within a predetermined or defined area or the plurality of areas. This advantageously takes into account the fact that the ceramic element is usually subject to undulation, i.e., the ceramic element is subject to waviness. In particular, the skilled person understands a waviness to be a modulation of the general flat course of the ceramic element, viewed over several millimeters or centimeters along a direction running parallel to the main extension plane. This distinguishes such an undulation from a surface roughness of the ceramic element, which is usually additionally present on the ceramic element. By including such an undulation of the ceramic element, which is generally unavoidable, in the determination of the thickness, it is taken into account that the bonding layer may vary due to the undulation, in particular may be greater in valley areas of the ceramic element than in mountain areas of the ceramic element.

Preferably, the proportion of active metal in the bonding agent layer comprising an active metal is greater than 15 weight percent, more preferably greater than 20 weight percent, and most preferably greater than 25 weight percent.

Preferably, the bonding layer is formed over the entire surface, in particular without dis-continuity, i.e. continuously, between the at least one metal layer and the ceramic element. Preferably, it is provided that a ratio of a region in which no bonding layer is formed between the at least one metal layer and the ceramic element to the regions in which a bonding layer is formed between the at least one bonding layer and the ceramic element is less than 0.05 mm, preferably less than 0.02 mm and most preferably less than 0.007 mm. The skilled person understands in particular that, in order to form this ratio, the areas which are free of metal of the at least one metal layer due to the structuring are not taken into account.

Preferably, the thermal conductivity of the ceramic element is greater than 80 W/mK, more preferably greater than 90 W/mK and most preferably greater than 110 W/mK. Correspondingly high thermal conductivities continue to prove particularly advantageous for heat dissipation, especially in addition to the above-mentioned roughness of the surface. This prevents heat from accumulating in the ceramic element after rapid dissipation via the interface between the ceramic element and the metal layer. This makes corresponding metal-ceramic substrates particularly advantageous for high-performance electronic components that generate a great deal of heat during operation.

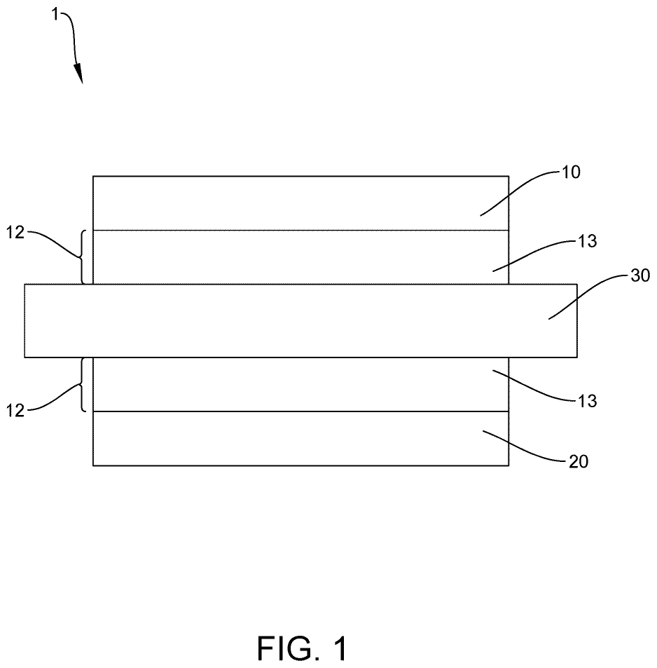

FIG. 1 shows a metal-ceramic substrate 1 according to a first exemplary embodiment of the present invention. Such metal-ceramic substrates 1 preferably serve as carriers or printed circuit boards for electronic or electrical components which can be connected to the at least one metal layer 10 of the metal-ceramic substrate 1 on the component side thereof. It is preferably provided that the at least one metal layer 10 is structured in order to form corresponding conductor paths and/or connecting areas, i.e. in the produced metal-ceramic substrate 1, the at least one metal layer 10 comprises several metal sections which are electrically insulated from one another. The at least one metal layer 10 extending essentially along a main extension plane HSE and a ceramic element 30 extending along the main extension plane HSE are arranged on top of one another along a stacking direction S running perpendicular to the main extension plane HSE and are preferably joined to one another via a bonding layer 12. joined together. Preferably, the metal-ceramic substrate 1 comprises, in addition to the at least one metal layer 10, at least one further metal layer 20 which, viewed in the stacking direction S, is arranged on the side of the ceramic element 30 opposite the at least one metal layer 10 and is bonded to the ceramic element 30 via a further bonding layer 12′.

The at least one further metal layer 20 serves as backside metallization, which counter-acts bending of the metal-ceramic substrate 1, in particular of the metal-ceramic element, and/or as a heat sink, which is designed to dissipate heat input caused by electrical or electronic components on the metal-ceramic substrate 1.

In particular, the metal-ceramic substrate 1 has a bonding layer 12 arranged between the at least one metal layer 10 and the ceramic element 30. It has been shown to be advantageous if a thickness of the bonding layer 12 measured in the stacking direction S is comparatively thin. In addition, a comparatively thin thickness of the bonding layer 12 between the at least one metal layer 10 and the ceramic element 30 proves to be advantageous if an etching process is provided for structuring the at least one metal layer 10. For example, narrower isolation trenches, i.e., distances between individual metal sections of the at least one metal layer 10, can be realized.

Furthermore, the forming of a thinner bonding layer 12 proves to be advantageous in that it also allows a number of possible defects in the bonding layers 12, caused by material defects in any solder material used, to be further reduced.

In the example shown in FIG. 1, the bonding layer 12 is in particular a bonding agent layer 13 comprising an active metal. In this case, after bonding, the bonding agent layer 13 is preferably formed from a material composition comprising a compound of components of the ceramic element on the one hand and an active metal on the other hand. Since these are very brittle bonds, it is advantageous for the adhesive strength of the at least one metal layer 10 on the ceramic element 30 that this bonding agent layer 13 be as thin as possible. For example, the bonding agent layer 13 can form the bonding layer 12 if, for example, an active metal layer, in particular an active metal foil, is arranged for the bonding process between the ceramic element 30 and the metal layer 10 and the bonding process takes place via hot isostatic pressing. However, the bonding agent layer 13 can also be formed, for example, by an active metal layer, in particular an active metal foil, which is arranged between the ceramic element 30 and a solder base layer in order to produce the bond between the metal layer 10 and the ceramic element 30 via the system consisting of the active metal layer and the solder base layer. In this case, the bonding agent layer 13 forms part of the bonding layer 12.

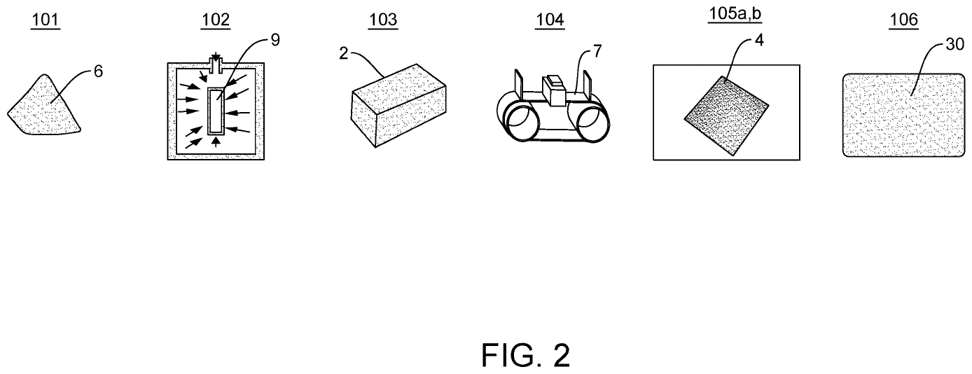

FIG. 2 schematically shows part of the method for producing a metal-ceramic substrate 1 intended as a printed circuit board according to an exemplary embodiment of the present invention. In particular, the schematic representation in FIG. 2 relates to the manufacturing and providing of a ceramic element 30, which in turn is used in a subsequent step not shown in FIG. 2 to form a metal-ceramic substrate 1 by bonding a metal layer 10 to the ceramic element 30 and structuring the metal layer 10 in order to form a component metallisation.

In particular, the method relates to the production of a ceramic element 30 or a nitrided wafer, which preferably comprises more than 80 weight percent silicon nitride, more preferably more than 85 weight percent silicon nitride and most preferably more than 91 weight percent silicon nitride. The remainder of the ceramic element is preferably formed from sintering aids, for example MgO and Y₂O₃. For this purpose, it is in particular provided that a starting block 2 is manufactured from a powder 6 and/or granulate in a preparatory step 101. The silicon powder 6 provided in the preparatory step 101 may, for example, contain a sintering aid such as magnesium oxide (MgO) and/or yttrium oxide (Y₂O₃) or similar. It is most preferably provided that catalysts, such as nickel or iron, are contained in the powder 6 or granulate. This has an advantageous effect on a sintering step 105b and a nitriding 105a in the following. Furthermore, it is conceivable that a powder mixture of silicon and silicon nitride is used to form the starting block 2. Preferably, this is an organically bound powder 6 or granulate which has been produced, for example, by means of spray granulation or build-up granulation.

In a second step of the process, a block element 9 is preferably formed from the powder 6 and/or granulate during block shaping 102, in particular by subjecting the powder 9 to a pressing process. By means of the pressing process, in particular by means of cold isostatic pressing or uniaxial pressing, it is thus possible to provide a block element 9 from the powder 6 or granulate. The block element 9 is preferably characterized by a first height with values between 170 mm and 210 mm, most preferably between 180 mm and 205 mm and most preferably between 190 mm and 200 mm and/or a width of 110 mm to 160 mm, more preferably from 120 mm to 150 mm and most preferably between 130 mm and 140 mm. Furthermore, the block has a depth which has a value between 5 mm and 500 mm, preferably between 15 mm and 300 mm and most preferably between 30 mm and 100 mm. In particular, the block element has a volume of 0.1 to 17 dm₃, preferably between 0.4 and 9 dm₃ and most preferably between 0.7 and 3 dm₃.

In a third process step of the embodiment shown in FIG. 2, it is provided that a pre-sintering step 103 is performed, in which a first density is set, which in particular should be smaller than the final second density in the ceramic element or the nitrided and sintered wafer 30, which is or are to be found in the produced metal-ceramic substrate 1. This advantageously provides an easy-to-handle starting block 4.

In the fourth process step of the embodiment shown in FIG. 2, it is provided that a wafer 4 is cut out of the starting block 2 by means of a saw. Such a release or detachment 104 of a wafer 4 from the starting block 2 proves to be particularly advantageous because it allows the thickness of the subsequent ceramic element to be individually adjusted as easily as possible. Furthermore, it has proven advantageous to set the density in the starting block 2 to a first density that is lower than a second density in the produced ceramic element 30, which is used as ceramic element 30 in the metal-ceramic substrate 1, since the porosity or a porosity of the starting block is increased in conjunction with the lower density. This simplifies the cutting process for cutting or detaching 104 a wafer 4 from the starting block 2. This proves to be advantageous because the manufacturing process is simplified and less intense action is exerted on the tool, i.e., the agent for detaching 104 the wafer 4. For example, a sawing device 7, in particular a multi-wire saw, is used as an agent for detaching a wafer 4 from the starting block 2.

In this context, it has proven particularly advantageous to use a diamond wire, a steel wire with silicon carbide or diamond slurry with PEG (polyethylene glycol) to separate a wafer from the starting block. It has been found to be advantageous to set an initial density of between 50 and 95% of the theoretical maximum density, in particular between 55 and 95% and most preferably between 60 and 92% of the theoretical maximum density. A protective gas is preferably used for this purpose.

In the fifth process step of the embodiment shown in FIG. 2, it is provided that the wafer 4 is converted into a silicon nitride wafer, i.e. a nitrided wafer 30, by nitriding 105a. Preferably, nitriding 105a is performed at a temperature below 1700° C., most preferably below 1650° C. and most preferably below 1500° C. In particular, the temperature is between 1300° C. and 1410° C. Heating is performed in a nitrogen atmosphere. In addition to nitriding 105a, a sintering step 105b is also provided in order to set a second density in the wafer 4 which is greater than the first density, in particular preferably greater than 95% of the maximum theoretical density. Preferably, nitriding 105b takes place before the sintering step 105b. This allows the specified porosity to be used so that nitrogen can penetrate as deeply as possible into the detached wafer 4 in order to carry out nitriding 105a as deeply and quickly as possible.

The sixth process step shown in FIG. 2 relates to providing the nitrided wafer as a ceramic element 30, in particular the silicon nitride ceramic element 30, in which surface polishing or surface treatment takes place in order to prepare it preferably for the subsequent bonding process in which the metal layer 10 is bonded to the ceramic element 30.

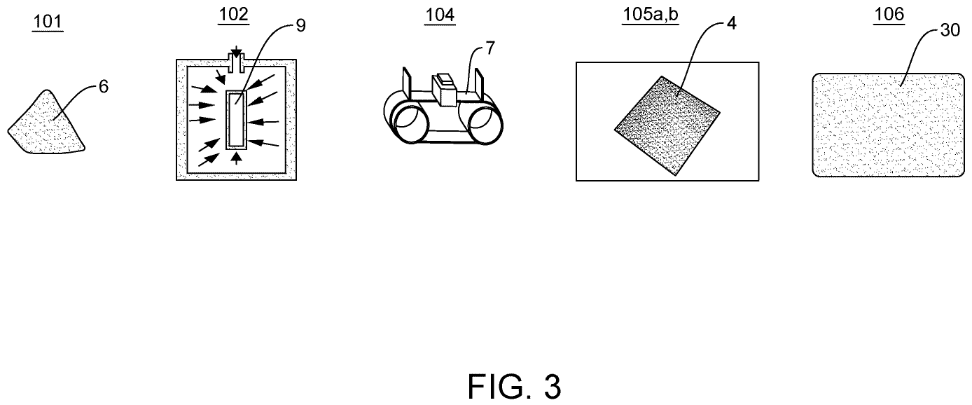

The embodiment shown in FIG. 3 differs essentially only in that, in order to provide the starting block 4, only pressing is carried out, whereby a block element 9 is formed from the granulate. The starting block 2 is thus present as a green compact before the wafer 4 is detached, and has not been subjected to a pre-sintering step 103 in order to set an initial density. The initial density is thus predetermined by the green compact. It has already been shown that, by following a corresponding procedure, it is possible to provide individual wafers 4 and then nitride and sinter them in order to provide the desired properties of the silicon nitride ceramic element 30. The advantage of this embodiment is that a pre-sintering step 103 can be omitted.

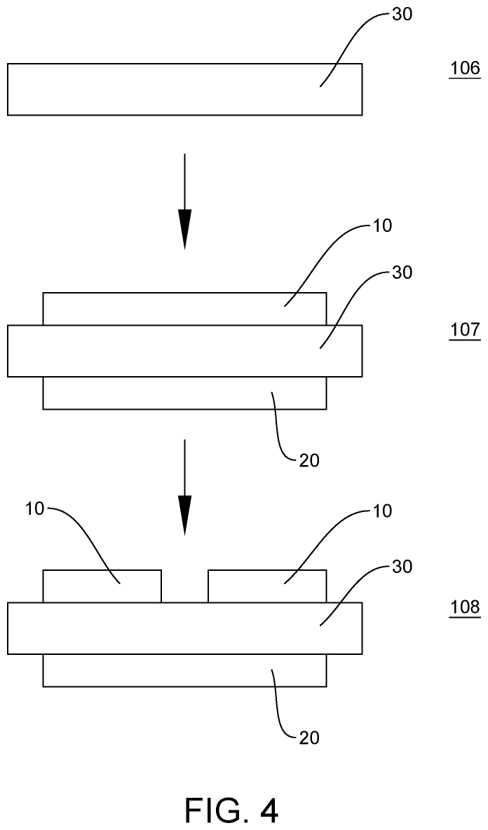

FIG. 4 shows a further part of the method for producing a metal-ceramic substrate serving as a printed circuit board. It relates to the bonding 107 of the metal layer 10 and the structuring 108 of the bonded metal layer 10. This involves the production of the metal-ceramic substrate 1 by bonding a metal layer 10 to a ceramic element 30, in particular to the ceramic element 30, which has been manufactured, for example, according to a method shown in FIG. 2 or 3. For example, a corresponding bonding can be carried out via an active soldering process or an ADB process. In particular, it is provided that, in addition to component metallisation, backside metallization 20 is carried out in order to counteract any deflections, in particular during operation. Following the connection process, it is preferably provided that metallisation is realised, for example by chemical and/or mechanical and/or optical detachment of metal material from the metal layer 10, for example in the form of component metallisation comprising conductor paths and connecting areas, in order to be able to use the metal-ceramic substrate 1 as a printed circuit board.

### REFERENCE NUMBERS

1 Metal-ceramic substrate
2 Starting block
4 Wafer
6 Powder, granulate
7 Sawing device
9 Block element
10 Metal layer
12 Bonding layer
13 Bonding agent layer
30 Nitrided wafer, ceramic element
101 Preparation step
102 Block shapes
103 Pre-sintering step
104 Detachment
105a Nitriding
105b Sintering step
106 Providing nitrided wafer
107 Bonding
108 Structuring

1-15. (canceled)

16. A method for producing a metal-ceramic substrate (1) intended as a printed circuit board, comprising:
providing a starting block (2) comprising silicon,
detaching (104) a wafer (4) from the starting block (2), wherein a sawing device (7) is used to detach the wafer (4),
nitriding (105a) the wafer (4) if the wafer (4) has a first density, and/or the starting block (2) if the starting block (2) has a first density, and
at least one sintering step (105b) for adjusting a second density in the wafer (4) and/or the starting block (2), wherein the second density is greater than the first density, and
bonding (107) a metal layer (10) to the sintered wafer (30) in order to form a metal-ceramic substrate (1).

17. The method according to claim 16, wherein the at least one sintering step (105b) is performed after the detachment (104).

18. The method according to claim 16, wherein a pre-sintering step (103) is performed prior to detachment (104) in order to adjust the first density.

19. The method according to claim 18, wherein the temperature in the pre-sintering step (103) is greater than 1700° C.

20. The method according to claim 18, wherein the sintering step (105b) after detachment (104) is shorter than the pre-sintering step (103).

21. The method according to claim 16, wherein a surface structure is realized during detachment (104).

22. The method according to claim 16, wherein the nitriding (105a) is performed before the detachment (104).

23. The method according to claim 16, wherein, for providing a starting block (2) comprising silicon, a powder (6) and/or a granulate is pressed into block shape (102).

24. The method according to claim 23, wherein the powder (6) and/or granulate comprises at least one sintering aid.

25. The method according to claim 23, wherein the powder (6) and/or granulate comprises a catalyst.

26. The method according to claim 16, wherein the powder (6) comprises, in addition to silicon, silicon nitride.

27. The method according to claim 16, wherein the metal layer (10) is bonded to the wafer (30) by means of an active soldering process and/or hot isostatic pressing.

28. The method according to claim 16, wherein the detached wafer (30) has at least partially a wedge-shaped form.

29. The method according to claim 16, wherein the starting block (2) is completely nitrided or partially nitrided.
